(19) United States
(12) Patent Application Publication
(10) Pub. No.: US 2026/0227682 A1
(43) Pub. Date: Aug. 6, 2026

(54) CONTROL METHOD, PROJECTION DEVICE, AND CONTROL PROGRAM

(71) Applicant: FUJIFILM Corporation, Tokyo (JP)

(72) Inventor: Kazuki INOUE, Saitama (JP)

(73) Assignee: FUJIFILM Corporation, Tokyo (JP)

(21) Appl. No.: 19/578,842

(22) Filed: Mar. 25, 2026

Related U.S. Application Data
(63) Continuation of application No. PCT/JP2024/031984, filed on Sep. 6, 2024.

(30) Foreign Application Priority Data
Sep. 27, 2023 (JP) 2023-165954

(51) Int. Cl. G03B 21/16; H05K 7/20

(52) U.S. Cl. CPC G03B 21/16; H05K 7/20209

(57) ABSTRACT

A projection device includes: a body part including a light source and a first cooling device; a head part including a light valve, a projection lens, and a second cooling device; a light transmission unit configured to transmit light output from the light source to the head part; and a processor. A housing of the body part and a housing of the head part are connected to each other via the light transmission unit. The head part includes a first temperature sensor that includes a temperature sensor of the light valve. The processor controls a set value of the second cooling device and an output power of the light source based on a temperature measured by the first temperature sensor, and the output power based on correspondence information between a change in the output power and a change in a temperature measured by the temperature sensor of the light valve.

### CROSS REFERENCE TO RELATED APPLICATION

This is a continuation of International Application No. PCT/JP2024/031984 filed on Sep. 6, 2024, and claims priority from Japanese Patent Application No. 2023-165954 filed on Sep. 27, 2023, the entire disclosures of which are incorporated herein by reference.

### BACKGROUND OF THE INVENTION

### 1. Field of the Invention

The present invention relates to a control method, a projection device, and a storage medium storing a control program.

### 2. Description of the Related Art

JP2017-178767A discloses a projection device comprising a light source device, a projection device head, and an optical fiber that connects the two, in which three laser light sources are adopted as light sources of the light source device, three single-mode fibers are adopted as the optical fiber, a phosphor that converts laser light into visible light of three colors of RGB is provided on an end surface of the optical fiber on a projection device head side, and the projection device head has a digital micromirror device (DMD), a triangular prism, a projection lens, a stop, and an enlarged optical system, and switching of the laser light sources and an operation of the DMD are synchronized with each other.

JP1990-267535A (JP-H2-267535A) discloses a liquid crystal projection device comprising a base, a light guide that holds an optical fiber and a signal line inside, and a light emitting unit, in which emission light of a high-brightness lamp accommodated in the base is emitted to an incidence end of the optical fiber through a condenser lens, and is emitted from an emission end and is projected onto a screen as a video through a condenser lens, a liquid crystal panel, and a projection lens in the light emitting unit.

JP1990-118624A (JP-H2-118624A) discloses a liquid crystal projection device in which a light source unit and a liquid crystal panel unit are separately configured, light of a light source lamp is emitted to a condensing unit of an optical fiber and is emitted from an emission unit, emitted light is decomposed into three colors of RGB by a dichroic mirror for color decomposition in the liquid crystal panel unit, is emitted to a liquid crystal panel driven by image signals of the three colors, and is transmitted from the liquid crystal panel as video light modulated by the image signals, and is synthesized by a dichroic prism for color synthesis and is projected onto a screen through a lens.

JP2014-115558A discloses a projection device comprising a body part, an optical fiber part, a flexible arm part, and a projection optical system, in which the body part has an illumination device, a color separation light guide optical system, a condenser lens, a light modulation unit, and a light synthesis unit, the optical fiber part extends through an inside of the flexible arm part, guides light from the light modulation unit to the projection optical system, and the projection optical system has a built-in projection lens and projects light from the optical fiber part as a projection image.

### SUMMARY OF THE INVENTION

One embodiment according to the disclosed technology provides a projection device that can be flexibly installed, a control method, and a storage medium storing a control program.
(1)

A projection device comprising: a body part including a light source and a first cooling device; a head part including a light valve, a projection lens, and a second cooling device; and a light transmission unit configured to transmit light output from the light source to the head part, in which a housing of the body part and a housing of the head part are connected to each other via the light transmission unit.
(2)

The projection device according to (1), in which the head part is configured to emit the light transmitted by the light transmission unit via the light valve and the projection lens.
(3)

The projection device according to (1) or (2), in which the housing of the body part and the housing of the head part are installed at positions different from each other.
(4)

The projection device according to any one of (1) to (3), in which the light transmission unit is flexible.
(5)

The projection device according to any one of (1) to (4), in which the body part includes a rotary member that transmits or reflects light, and is configured to output the light emitted from the light source to the light transmission unit via the rotary body.
(6)

The projection device according to any one of (1) to (5), in which the head part includes a rotary member that transmits or reflects light, and is configured to emit the light transmitted by the light transmission unit via the rotary body, the light valve, and the projection lens.
(7)

The projection device according to any one of (1) to (6), further comprising: a processor, in which the head part includes a first temperature sensor, and the processor is configured to control a set value of the second cooling device based on a temperature measured by the first temperature sensor and control an output power of the light source based on the set value of the second cooling device.
(8)

The projection device according to (7), in which the processor is configured to perform a control of reducing the output power of the light source in a case where the set value of the second cooling device reaches a predetermined value.
(9)

The projection device according to (8), in which the first cooling device and the second cooling device are cooling fans.
(10)

The projection device according to (8) or (9), in which the predetermined value is variable.
(11)

The projection device according to (9), in which the processor is configured to switch between a control of reducing the output power of the light source in a case where a rotation speed of the second cooling device reaches a first predetermined value, and control of reducing the output power of the light source in a case where the rotation speed of the second cooling device reaches a second predetermined value higher than the first predetermined value.
(12)

The projection device according to any one of (7) to (11), in which the first temperature sensor includes a temperature sensor of the light valve and an ambient air temperature sensor of the head part, and the processor is configured to control the output power of the light source based on a temperature measured by the temperature sensor of the light valve and a temperature measured by the ambient air temperature sensor of the head part.
(13)

The projection device according to any one of (7) to (12), in which the first temperature sensor includes a temperature sensor of the light valve, and the processor is configured to control the output power of the light source based on correspondence information between a change in the output power of the light source and a change in a temperature measured by the temperature sensor of the light valve.
(14)

The projection device according to any one of (7) to (13), in which the processor is configured to perform a control of lowering the output power of the light source, and perform a control of increasing the output power of the light source based on a temperature measured by the first temperature sensor.
(15)

The projection device according to (14), in which the body part includes a second temperature sensor, the first cooling device is a cooling fan, and the processor is configured to perform a control of increasing the output power of the light source, and perform a control of a rotation speed of the first cooling device based on a temperature measured by the second temperature sensor.
(16)

The projection device according to any one of (7) to (15), in which the body part includes a first communication unit, the head part includes a second communication unit that communicates with the first communication unit, and the processor is configured to perform a control by using communication between the first communication unit and the second communication unit.
(17)

A control method performed by a control device of a projection device including a body part including a light source and a first cooling device, a head part including a light valve, a projection lens, a second cooling device, and a first temperature sensor, and a light transmission unit that transmits light output from the light source to the head part, in which a housing of the body part and a housing of the head part are connected to each other through the light transmission unit, the control method comprising: controlling, by a processor of the control device, a set value of the second cooling device based on a temperature measured by the first temperature sensor; and controlling an output power of the light source based on the set value of the second cooling device.
(18)

A control program for a projection device including a body part including a light source and a first cooling device, a head part including a light valve, a projection lens, a second cooling device, and a first temperature sensor, and a light transmission unit that transmits light output from the light source to the head part, in which a housing of the body part and a housing of the head part are connected to each other through the light transmission unit, the control program causing a processor of the projection device to execute processing of: controlling a set value of the second cooling device based on a temperature measured by the first temperature sensor; and controlling output power of the light source based on the set value of the second cooling device.

According to the present invention, it is possible to provide a projection device that can be flexibly installed, a control method, and a storage medium storing a control program.

### BRIEF DESCRIPTION OF THE DRAWINGS

FIG. 1 is a schematic diagram showing an example of a projection device 1 according to the embodiment.

FIG. 2 is a diagram showing an example of a configuration of a projection device 1.

FIG. 3 is a diagram showing a first configuration example of the projection device 1 of a DLP method.

FIG. 4 is a diagram showing a second configuration example of the projection device 1 of the DLP method.

FIG. 5 is a diagram showing a third configuration example of the projection device 1 of the DLP method.

FIG. 6 is a diagram showing an example of an appearance of a head part 20.

FIG. 7 is a diagram showing an example of a fan for intake and a fan for exhaust provided in the head part 20.

FIG. 8 is a diagram showing the head part 20 shown in FIG. 7 as viewed from a ceiling 5 side.

FIG. 9 is a diagram showing an example of an appearance of a body part 10.

FIG. 10 is a diagram showing an example in which two body parts are installed side by side.

FIG. 11 is a diagram showing an example of a configuration of the projection device 1 of the DLP method including a sensor.

FIG. 12 is a flowchart showing an example of control of a fan by a control unit 131.

FIG. 13 is a flowchart of control of the fan following FIG. 12.

FIG. 14 is a flowchart showing a modification example of the control of the fan shown in FIG. 12.

FIG. 15 is a flowchart showing a modification example of the control of the fan shown in FIG. 14.

FIG. 16 is a flowchart showing a modification example of the control of the fan shown in FIG. 13.

FIG. 17 is a diagram showing an example of a configuration of the projection device 1 of an LCD method.

FIG. 18 is a diagram showing a first modification example of the configuration of the projection device 1.

FIG. 19 is a diagram showing an example of a specific configuration of the first modification example shown in FIG. 18.

FIG. 20 is a diagram showing a second modification example of the configuration of the projection device 1.

FIG. 21 is a diagram showing an example of a specific configuration of the second modification example shown in FIG. 20.

### DESCRIPTION OF THE PREFERRED EMBODIMENTS

Hereinafter, an example of an embodiment of the present invention will be described with reference to the drawings.

### Projection Device 1 of Embodiment

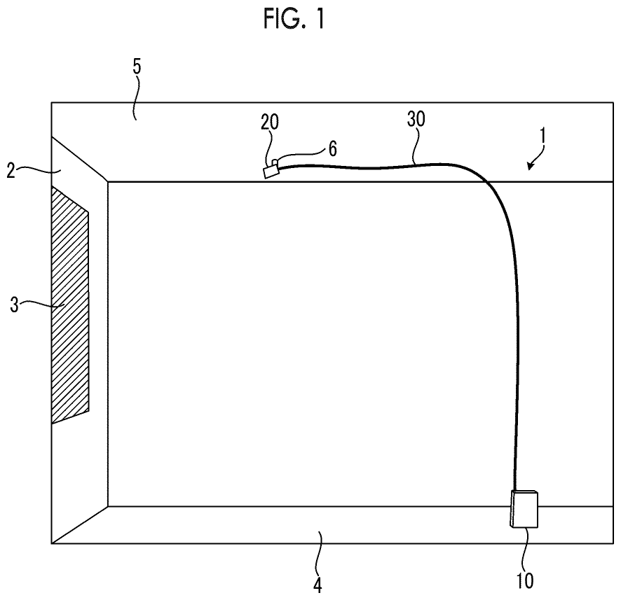

FIG. 1 is a schematic diagram showing an example of a projection device 1 of the embodiment. As shown in FIG. 1, the projection device 1 comprises a body part 10, a head part 20, and an optical fiber 30. The optical fiber 30 is an example of a “light transmission unit” in the present invention.

The body part 10 and the head part 20 in the projection device 1 are provided in respective independent housings. The body part 10 is installed on, for example, a floor 4 of a room. In addition, the head part 20 is installed by being suspended from, for example, a ceiling 5 of the room via a mounting bracket 6. A housing of the body part 10 installed on the floor 4 and a housing of the head part 20 installed on the ceiling 5 are connected to each other through the optical fiber 30. The projection device 1 is a separable type projection device in which the housing of the body part 10 and the housing of the head part 20 are installed at different positions. The projection device 1 projects a projection image 3 from the head part 20 toward a projection target surface such as a wall 2 of the room.

The head part 20 is a device including a projection lens or the like that projects the projection image 3 toward the wall 2 of the room. Therefore, the head part 20 is installed at a location (ceiling 5 or the like) that is not so far from an observer who observes the projection image 3 in the room. On the other hand, the body part 10 is a device including a light source unit or the like, and light output from the light source is transmitted to the head part 20 through the optical fiber 30. Therefore, the body part 10 can be installed at a location that is away from the observer in the room, for example, a rear end of the room or an adjacent room, as compared with the head part 20.

### Configuration of Projection Device 1

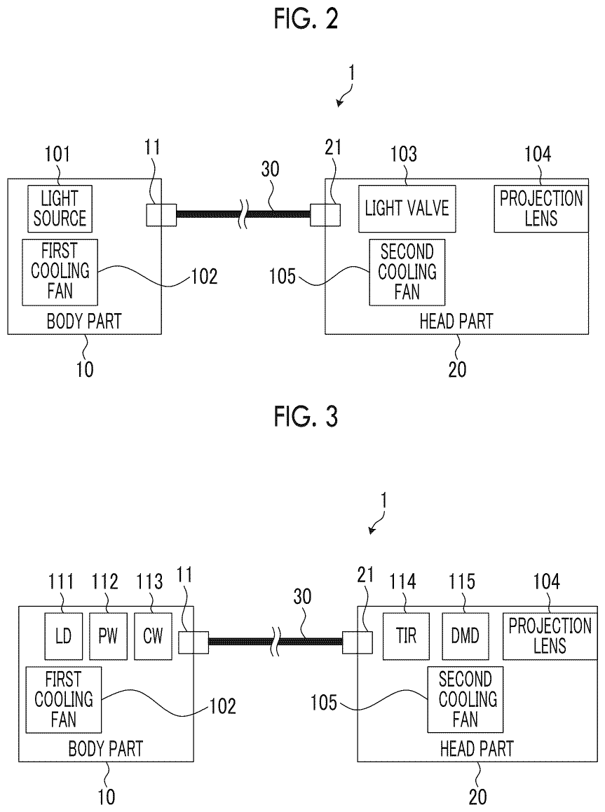

FIG. 2 is a diagram showing an example of a configuration of the projection device 1. As shown in FIG. 2, the body part 10 of the projection device 1 comprises a light source 101, a first cooling fan 102, and a connector 11. In addition, the head part 20 of the projection device 1 comprises a light valve 103, a projection lens 104, a second cooling fan 105, and a connector 21.

As the light source 101, for example, a laser diode (LD) light source, a light emitting diode (LED) light source, or a mercury lamp light source is used. The first cooling fan 102 is a fan for cooling the light source 101. The first cooling fan 102 is an example of a “first cooling device” in the present invention. The connector 11 is a connector to which the optical fiber 30 can be connected.

The light valve 103 is a device that modulates light from the light source 101 based on image data. The light valve 103 is, for example, a digital micromirror device (DMD) in a projection device of a digital lighting processing (DLP) method (registered trademark), and is a liquid crystal display (LCD) in a projection device of an LCD method. Light output from the light valve 103 is projected from the projection lens 104.

The projection lens 104 projects an image onto a projection target surface. The second cooling fan 105 is a fan for cooling the light valve 103. The second cooling fan 105 is an example of a “second cooling device” in the present invention. The connector 21 is a connector to which the optical fiber 30 can be connected. The head part 20 performs projection by emitting light transmitted from the body part 10 through the optical fiber 30 to, for example, a projection target such as a screen through the light valve 103 and the projection lens 104.

As described above, the optical fiber 30 is a fiber that connects the housing of the body part 10 and the housing of the head part 20. The housing of the body part 10 and the housing of the head part 20 are connected to each other through the optical fiber 30, instead of being directly connected to each other. That is, the body part 10 and the head part 20 can be installed at different positions.

As a result, the projection device 1 can be flexibly installed. For example, the head part 20 can be installed at a position suitable for projection (a position close to the observer, a position easily visible from the observer), and the body part 10 can be installed at a position away from the observer, a position not easily visible from the observer.

In addition, the optical fiber 30 functions as an integrator that can make a non-uniformity of light transmitted from the body part 10 to the head part 20 uniform. In addition, the optical fiber 30 is a flexible connecting member.

According to the projection device 1 having such a configuration, since the head part 20 is separated from the body part 10, the head part 20 can be reduced in size, and a relative positional relationship between the body part 10 and the head part 20 can be changed. Therefore, the body part 10 and the head part 20 can be flexibly installed at suitable locations and can be easily removed, and thus maintenance is easy.

### Configuration Example of DLP Method Projection Device 1 of DLP Method

A configuration example of the projection device 1 of the DLP method will be described with reference to FIGS. 3 to 5.

### First Configuration Example

FIG. 3 is a diagram showing a first configuration example of the projection device 1 of the DLP method. As shown in FIG. 3, the body part 10 of the projection device 1 of the first configuration example comprises a laser diode (LD) 111, a phosphor wheel (PW) 112, a color wheel (CW) 113, the first cooling fan 102, and the connector 11. In addition, the head part 20 of the projection device 1 of the first configuration example comprises a total internal reflection prism (TIR prism) 114, a DMD 115, the projection lens 104, the second cooling fan 105, and the connector 21.

In the LD 111 in the present example, a blue LD is used. The PW 112 transmits blue light output from the LD 111 to generate yellow light. The CW 113 transmits blue light and yellow light output from the PW 112 to generate red light and green light. The PW 112 and the CW 113 are examples of a “rotary body” in the present invention. The rotary body transmits or reflects light. The LD 111, the PW 112, and the CW 113 correspond to the light source 101 described in FIG. 2. Red, green, and blue (RGB) light generated by the body part 10 is transmitted to the head part 20 through the optical fiber 30. The first cooling fan 102 and the connector 11 are as described in FIG. 2.

The TIR 114 is, for example, a combination of two triangular prisms, and performs spectral separation or change of an optical path in order to cause light transmitted from the body part 10 to be incident on the DMD 115. The DMD 115 generates RGB light by repeatedly switching at a high speed in synchronization with the rotation of the CW 113. The DMD 115 corresponds to the light valve 103 described in FIG. 2. Light output from the DMD 115 is projected from the projection lens 104. The second cooling fan 105 and the connector 21 are as described in FIG. 2.

### Second Configuration Example

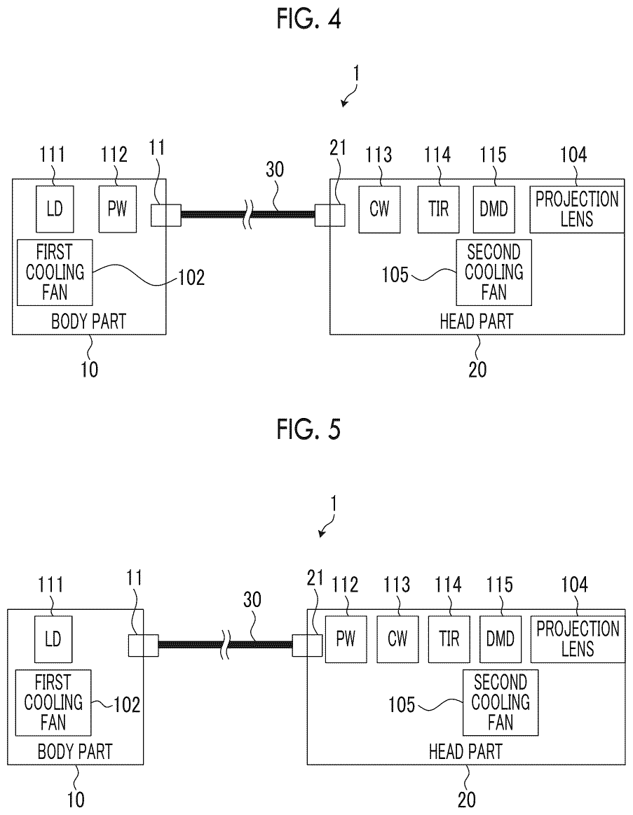

FIG. 4 is a diagram showing a second configuration example of the projection device 1 of the DLP method. As shown in FIG. 4, the body part 10 of the projection device 1 of the second configuration example comprises the LD 111, the PW 112, the first cooling fan 102, and the connector 11. In addition, the head part 20 of the projection device 1 of the second configuration example comprises the CW 113, the TIR 114, the DMD 115, the projection lens 104, the second cooling fan 105, and the connector 21. The projection device 1 of the second configuration example is different from the projection device 1 of the first configuration example shown in FIG. 3 in that the CW 113 that is the rotary body is provided in the head part 20. The projection device 1 of the second configuration example is used, for example, in a case where an output light amount of the light source is high.

### Third Configuration Example

FIG. 5 is a diagram showing a third configuration example of the projection device 1 of the DLP method. As shown in FIG. 5, the body part 10 of the projection device 1 of the third configuration example comprises the LD 111, the first cooling fan 102, and the connector 11. In addition, the head part 20 of the projection device 1 of the third configuration example comprises the PW 112, the CW 113, the TIR 114, the DMD 115, the projection lens 104, the second cooling fan 105, and the connector 21. The projection device 1 of the third configuration example is different from the projection device 1 of the first configuration example shown in FIG. 3 in that the PW 112 and the CW 113 that are the rrotary bodies are provided in the head part 20. The projection device 1 of the third configuration example is used in the same manner as in the second configuration example in a case where the output light amount of the light source is high.

According to the first to third configuration examples of the projection device 1 of the DLP method, the head part 20 can be reduced in size, and a relative positional relationship between the body part 10 and the head part 20 can be changed, so that the projection device 1 is easy to install and remove, and is easy to maintain.

### Fan for Intake/Exhaust of Head Part 20

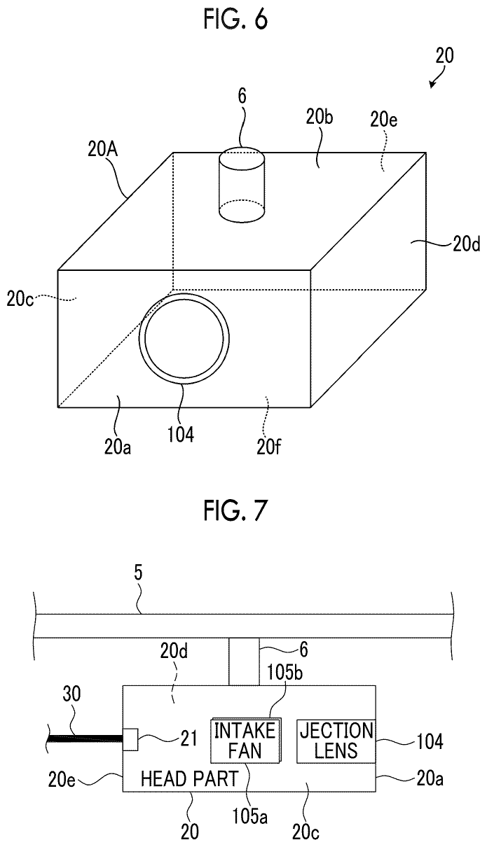

FIG. 6 is a diagram showing an example of an appearance of the head part 20. As shown in FIG. 6, the head part 20 has a housing 20A that is formed in, for example, a box shape. In the housing 20A, a surface on which the projection lens 104 is provided is defined as a front surface 20a, and a surface on which the mounting bracket 6 for installing the head part 20 is provided is defined as an upper surface 20b. For example, in a case where the head part 20 is attached to the ceiling 5 of the room via the mounting bracket 6, surfaces on which a fan for intake can be disposed in the head part 20 are the front surface 20a, side surfaces 20c and 20d, a rear surface 20e, and a lower surface 20f, excluding the upper surface 20b on which the mounting bracket 6 is provided.

In addition, surfaces on which a fan for exhaust can be disposed in the head part 20 are the side surfaces 20c and 20d, the rear surface 20e, and the lower surface 20f, excluding the front surface 20a on which the projection lens 104 is provided and the upper surface 20b on which the mounting bracket 6 is provided. In a case of the head part 20 that is reduced in size, it is difficult to secure a space for a fan on the upper surface 20b on which the mounting bracket 6 is provided. In addition, it is preferable that a fan for exhaust that discharges warmed air is not provided on the front surface 20a on which the projection lens 104 is provided.

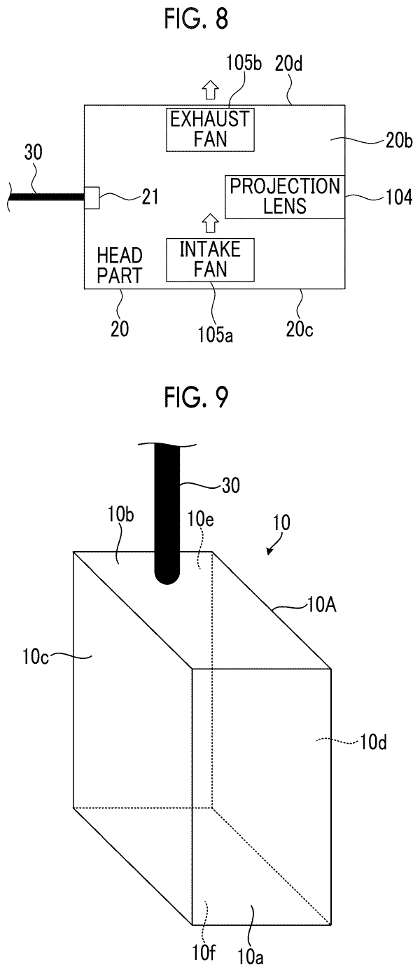

FIG. 7 is a diagram showing an example of a fan for intake and a fan for exhaust provided in the head part 20. FIG. 8 is a diagram showing the head part 20 shown in FIG. 7 as viewed from the ceiling 5 (upper surface 20b) side. In the head part 20 shown in FIGS. 7 and 8, the intake fan 105a is provided on the right side surface 20c of the housing 20A, and the exhaust fan 105b is provided on the left side surface 20d of the housing 20A.

### Fan for Intake/Exhaust of Body Part 10

FIG. 9 is a diagram showing an example of an appearance of the body part 10. As shown in FIG. 9, the body part 10 has a housing 10A that is formed in, for example, a box shape. In the housing 10A, a surface to which the optical fiber 30 is connected is defined as an upper surface 10b, and a surface that is installed on the floor 4 of the room is defined as a lower surface 10f.

For example, in a case where the body part 10 is installed on the floor 4 of the room, surfaces on which a fan for intake and a fan for exhaust can be disposed in the body part 10 are the front surface 10a, the upper surface 10b, the side surfaces 10c and 10d, and the rear surface 10e, excluding the lower surface 10f facing the floor 4. However, surfaces on which the fan for exhaust can be disposed may be the front surface 10a, the side surfaces 10c and 10d, and the rear surface 10e, excluding the upper surface 10b to which the optical fiber 30 is connected and the lower surface 10f facing the floor 4. In consideration of the temperature characteristics of the optical fiber 30, the fan for exhaust that discharges the warmed air may not be provided on the upper surface 10b.

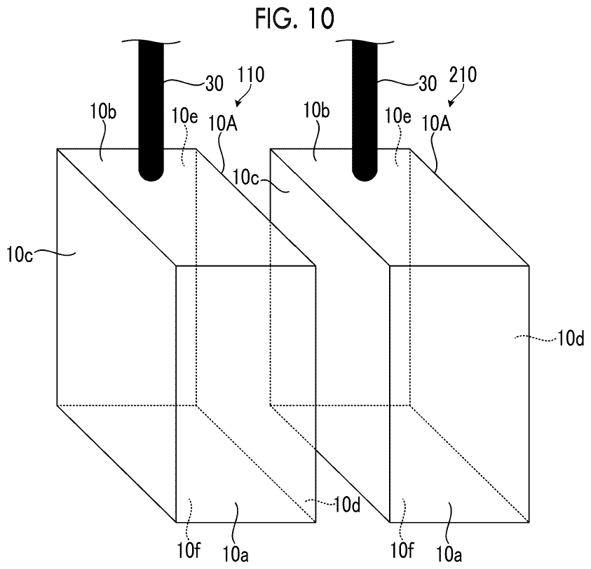

FIG. 10 is a diagram showing an example in which two body parts are installed side by side. As shown in FIG. 10, in a case where the body part 110 and the body part 210 are installed side by side, the left side surface 10d of the body part 110 and the right side surface 10c of the body part 210 are disposed to face each other. Therefore, in a case where two body parts are installed side by side, the fan for intake and the fan for exhaust are not provided on each of the facing surfaces.

Therefore, in the present example, surfaces on which the fan for intake and the fan for exhaust can be disposed in the body part 110 are the front surface 10a, the upper surface 10b, the side surface 10c, and the rear surface 10e, excluding the lower surface 10f facing the floor 4 and the left side surface 10d facing the adjacent body part 210. In addition, surfaces on which the fan for intake and the fan for exhaust can be disposed in the body part 210 are the front surface 10a, the upper surface 10b, the side surface 10d, and the rear surface 10e, excluding the lower surface 10f facing the floor 4 and the right side surface 10c facing the adjacent body part 110. However, as in the case of FIG. 9, the fan for exhaust may not be provided on the upper surface 10b to which the optical fiber 30 is connected.

### Configuration Example of DLP Method Projection Device 1 Including Sensor

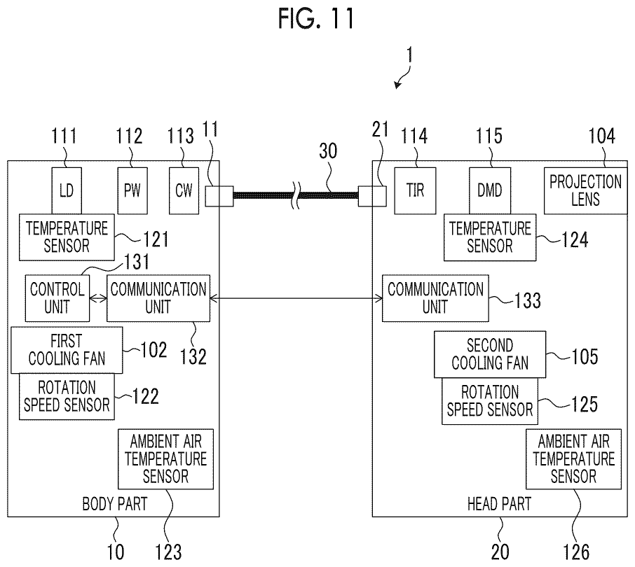

FIG. 11 is a diagram showing an example of a configuration of the projection device 1 of the DLP method including a sensor. The body part 10 of the projection device 1 of the present example comprises the LD 111, the PW 112, the CW 113, the first cooling fan 102, the connector 11, a temperature sensor 121, a rotation speed sensor 122, an ambient air temperature sensor 123, a control unit 131, and a communication unit 132. In addition, the head part 20 of the projection device 1 of the present example comprises the TIR 114, the DMD 115, the projection lens 104, the second cooling fan 105, the connector 21, a temperature sensor 124, a rotation speed sensor 125, an ambient air temperature sensor 126, and a communication unit 133.

The temperature sensor 121 is a sensor for measuring a temperature of the LD 111. The temperature sensor 121 is an example of a “second temperature sensor” in the present invention. The rotation speed sensor 122 is a sensor for measuring a rotation speed of the first cooling fan 102. The ambient air temperature sensor 123 is a sensor for measuring a temperature around the housing of the body part 10. For example, the ambient air temperature sensor 123 is provided near an intake port of the body part 10, and measures a temperature of air sucked into the housing from the intake port. The ambient air temperature sensor 123 is an example of a “second temperature sensor” in the present invention.

The temperature sensor 124 is a sensor for measuring a temperature of the DMD 115. The temperature sensor 124 is an example of a “first temperature sensor” in the present invention. The rotation speed sensor 125 is a sensor for measuring a rotation speed of the second cooling fan 105. The ambient air temperature sensor 126 is a sensor for measuring a temperature around the housing of the head part 20. For example, the ambient air temperature sensor 126 is provided near an intake port of the head part 20, and measures a temperature of air sucked into the housing from the intake port. The ambient air temperature sensor 126 is an example of a “first temperature sensor” in the present invention.

The control unit 131 controls an operation of the body part 10 and the head part 20. The control unit 131 is an example of a “processor” in the present invention.

For example, the control unit 131 controls the rotation speed of the second cooling fan 105 based on the temperature measured by the temperature sensor 124 or the ambient air temperature sensor 126, and controls the output power of the LD 111 based on the rotation speed of the second cooling fan 105.

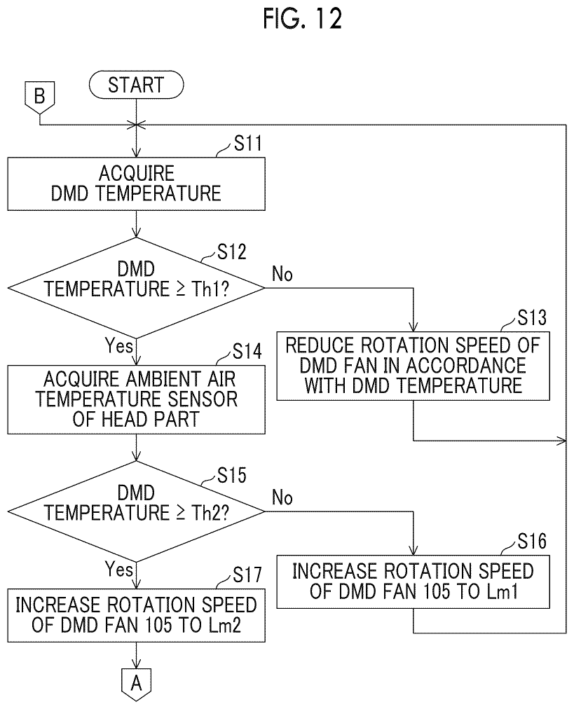

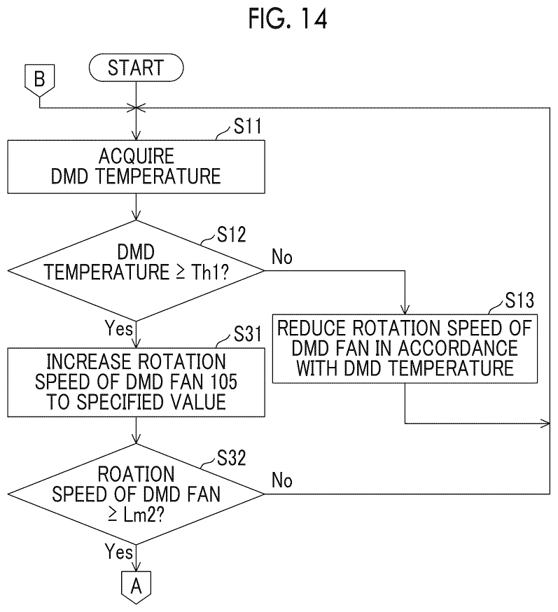

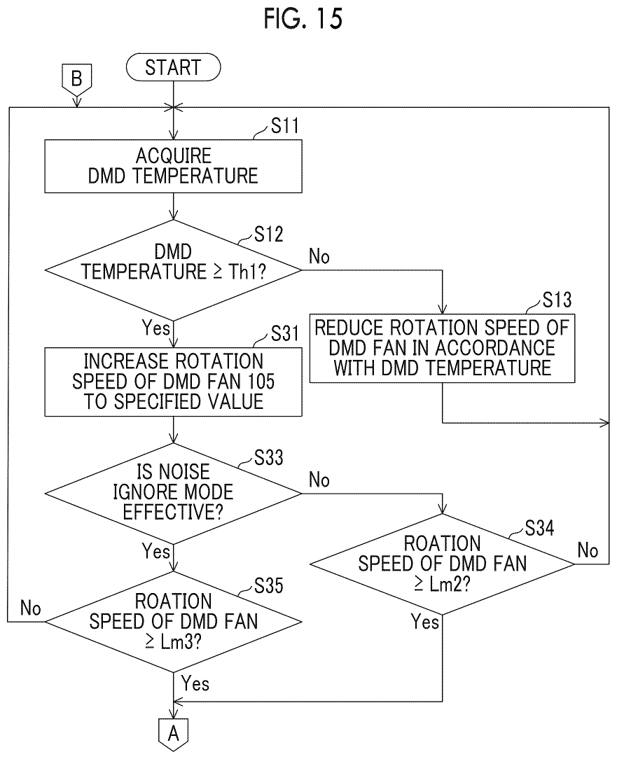

In addition, the control unit 131 performs control of reducing the output power of the LD 111 in a case where the rotation speed of the second cooling fan 105 reaches a predetermined value. The rotation speed of the second cooling fan 105 reaching the predetermined value means that the rotation speed of the second cooling fan 105 is equal to or higher than the predetermined value. The case where the rotation speed of the second cooling fan 105 reaches the predetermined value includes, for example, a case where the rotation speed is increased to the predetermined value by control (described later in FIG. 12) and a case where the rotation speed is increased to the predetermined value or higher by control of increasing the rotation speed by a certain amount (described later in FIGS. 14 and 15).

In addition, the control unit 131 is configured to switch between control of reducing the output power of the LD 111 in a case where the rotation speed of the second cooling fan 105 reaches a first predetermined value, and control of reducing the output power of the LD 111 in a case where the rotation speed of the second cooling fan 105 reaches a second predetermined value higher than the first predetermined value. The predetermined value of the rotation speed can be changed by setting. The switching is, for example, switching that can be performed by user setting.

In addition, the control unit 131 controls the output power of the LD 111 based on the temperature measured by the temperature sensor 124 and the temperature measured by the ambient air temperature sensor 126. For example, the control unit 131 reduces the output power of the LD 111 in a case where the temperature of the temperature sensor 124 reaches a predetermined value (Th1) and the temperature of the ambient air temperature sensor 126 reaches a predetermined value (Th2). Th1 is an example of a threshold value (for example, an operation upper limit temperature) of the temperature of the DMD 115. Th2 is an example of a threshold value (for example, a surrounding upper limit temperature) of the ambient air temperature on the head part 20 side.

In addition, the control unit 131 controls the output power of the LD 111 based on correspondence information between a change in the output power of the LD 111 and a change in the temperature measured by the temperature sensor 124. For example, the control unit 131 reduces the output power of the LD 111 to a temperature that is slightly lower (by a margin) than the predetermined value (Th1) of the temperature measured by the temperature sensor 124. The correspondence information is generated, for example, by simulation or experiment in a design stage, or by calibration after manufacturing or after installation.

In addition, the control unit 131 performs control of increasing the output power of the LD 111 based on the temperature measured by the temperature sensor 124 or the ambient air temperature sensor 126 after performing control of reducing the output power of the LD 111. The increase in the output power is, for example, returning to the output power before the reduction.

In addition, the control unit 131 controls the rotation speed of the first cooling fan 102 based on the temperature measured by the temperature sensor 121 or the ambient air temperature sensor 123 after performing control of increasing the output power of the LD 111.

The communication unit 132 is an interface that can communicate with the communication unit 133 of the head part 20. The communication unit 132 is an example of a “first communication unit” in the present invention. The communication unit 133 is an interface that can communicate with the communication unit 132 of the body part 10. The communication unit 133 is an example of a “second communication unit” in the present invention. The control unit 131 performs control of the body part 10 and the head part 20 by using the communication between the communication unit 132 and the communication unit 133. For example, the control unit 131 receives sensor information acquired by each of the sensors 124 to 126 on the head part 20 side, or transmits a control signal for controlling the rotation of the second cooling fan 105 on the head part 20 side. The communication between the communication unit 132 and the communication unit 133 may be wired communication or wireless communication. In the present example, the control unit 131 is provided on the body part 10 side, but the present invention is not limited to this, and the control unit 131 may be provided on the head part 20 side, for example.

For example, in a case where the control unit 131 is provided in the body part 10 or an external device (for example, a personal computer) connected to the body part 10, the control unit 131 uses the communication with the head part 20 to acquire the temperature of the temperature sensor 124 of the head part 20, control the output power of the LD 111 based on the acquired temperature, and control the rotation speed of the second cooling fan 105 of the head part 20 based on the acquired temperature. In addition, in a case where the control unit 131 is provided in the head part 20, the communication is used to acquire the temperature of the temperature sensor 121 of the body part 10, control the output power of the LD 111 of the body part 10 based on the acquired temperature, and control the rotation speed of the first cooling fan 102 of the body part 10 based on the acquired temperature.

### Control of Fan by Control Unit 131

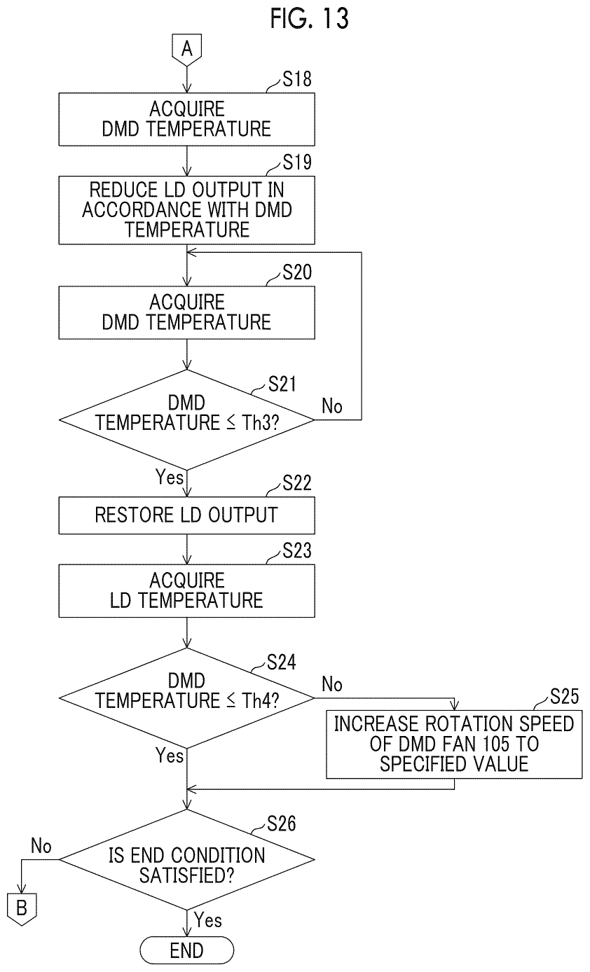

FIGS. 12 and 13 are flowcharts showing an example of the control of the fan by the control unit 131. The control unit 131 starts main processing, for example, in a case where the projection device 1 is activated.

First, the control unit 131 acquires the temperature of the DMD 115 measured by the temperature sensor 124 of the head part 20 via the communication units 132 and 133 (step S11).

Next, the control unit 131 determines whether or not the temperature of the DMD 115 acquired in step S11 has risen to, for example, Th1 [°C] or higher (step S12). Th1 is an example of an operation upper limit temperature of the DMD 115.

In step S12, in a case where the temperature of the DMD 115 has not risen to Th1 or higher (step S12: No), the control unit 131 performs control of reducing the rotation speed of the second cooling fan 105 that cools the DMD 115 in accordance with the acquired temperature of the DMD 115 via the communication units 132 and 133 (step S13). For example, in a case where the temperature of the DMD 115 is sufficiently lower than Th1, the control unit 131 slightly reduces the rotation speed of the second cooling fan 105. The control unit 131 returns to step S11 to repeat each processing after reducing the rotation speed of the second cooling fan 105. The control unit 131 may skip the processing of step S13.

In step S12, in a case where the temperature of the DMD 115 has risen to Th1 or higher (step S12: Yes), the control unit 131 acquires the ambient air temperature of the head part 20 measured by the ambient air temperature sensor 126 of the head part 20 via the communication units 132 and 133 (step S14).

Next, the control unit 131 determines whether or not the ambient air temperature of the head part 20 acquired in step S14 has risen to, for example, Th2 [°C] or higher (step S15). Th2 is an example of a surrounding upper limit temperature of the head part 20.

In step S15, in a case where the ambient air temperature of the head part 20 is not Th2 or higher (step S15: No), the control unit 131 performs control of increasing the rotation speed of the second cooling fan 105 to, for example, Lm1 [rpm] via the communication units 132 and 133 (step S16). Lm1 is an example of a specified value of the rotation speed of the second cooling fan 105. The specified value is a recommended rotation speed of the fan that is allowable as a magnitude of noise due to the rotation of the fan. The control unit 131 returns to step S11 to repeat each processing after increasing the rotation speed of the second cooling fan 105 to Lm1.

In step S15, in a case where the ambient air temperature of the head part 20 is Th2 or higher (step S15: Yes), the control unit 131 performs control of increasing the rotation speed of the second cooling fan 105 to, for example, Lm2 [rpm] via the communication units 132 and 133 (step S17). Lm2 is an example of an allowable upper limit value of the rotation speed of the second cooling fan 105. The allowable upper limit value is, for example, a limit rotation speed slightly before a magnitude of noise due to the rotation of the fan is not allowable.

Next, the control unit 131 proceeds to the processing of FIG. 13, and acquires the temperature of the DMD 115 measured by the temperature sensor 124 of the head part 20 again (step S18).

Next, the control unit 131 reduces the output of the light of the LD 111 in accordance with the temperature of the DMD 115 acquired in step S18 (step S19). For example, the control unit 131 reduces the output power of the LD 111 such that the temperature of the DMD 115 is slightly lower than Th1. The control unit 131 reduces the output power based on correspondence information in which a relationship between a change (reduction amount) in the output power of the LD 111 and a change (reduction amount) in the temperature of the DMD 115 is recorded.

Next, the control unit 131 acquires the temperature of the DMD 115 measured by the temperature sensor 124 of the head part 20 again (step S20).

Next, the control unit 131 determines whether or not the temperature of the DMD 115 acquired in step S20 is, for example, Th3 [°C] or lower (step S21). Th3 is a temperature lower than Th1. Th3 is a temperature at which, for example, even in a case where the output of the LD 111 reduced in step S19 is restored to the original output, the temperature of the DMD 115 is assumed not to exceed Th1.

In step S21, in a case where the temperature of the DMD 115 is not Th3 or lower (step S21: No), the control unit 131 returns to step S20 to repeat each processing.

In step S21, in a case where the temperature of the DMD 115 is Th3 or lower (step S21: Yes), the control unit 131 restores the output of the LD 111 to the output before step S19 (step S22).

Next, the control unit 131 acquires the temperature of the LD 111 measured by the temperature sensor 121 (step S23). In a case of acquiring the temperature of the LD 111, the temperature is measured after waiting until the temperature is stabilized to some extent. In particular, since there is a fluctuation immediately after the rotation speed of the fan or the output of the LD 111 is changed, the temperature is measured after waiting.

Next, the control unit 131 determines whether or not the temperature of the LD 111 acquired in step S23 is, for example, Th4 [°C] or lower (step S24). Th4 is an example of a threshold value (for example, an operation upper limit temperature) of the temperature of the LD 111.

In step S24, in a case where the temperature of the LD 111 is not Th4 or lower (step S24: No), the control unit 131 increases the rotation speed of the first cooling fan 102 (LD fan) that cools the LD 111 to the specified value (step S25). The specified value is an example of an upper limit of the rotation speed of the first cooling fan 102. The control unit 131 proceeds to step S26 to determine whether or not an end condition of the main processing is satisfied after increasing the rotation speed of the first cooling fan 102 to the specified value (step S26). The end condition is, for example, turning off the power of the projection device 1.

In step S24, in a case where the temperature of the LD 111 is Th4 or lower (step S24: Yes), the control unit 131 proceeds to step S26 to determine whether or not the end condition of the main processing is satisfied (step S26).

In step S26, in a case where the end condition of the main processing is not satisfied (step S26: No), the control unit 131 returns to step S11 of FIG. 12 to repeat each processing. In step S26, in a case where the end condition of the main processing is satisfied (step S26: Yes), the control unit 131 ends the main processing.

According to the projection device 1 comprising the cooling fan, the head part 20 can be reduced in size, and a relative positional relationship between the body part 10 and the head part 20 can be changed, so that, for example, it is possible to perform control of suppressing the rotation speed of the second cooling fan 105 on the head part 20 side to the allowable upper limit value Lm2 that does not cause noise with respect to the surroundings, and increasing the rotation speed of the first cooling fan 102 on the body part 10 side to the upper limit value. Therefore, it is possible to efficiently manage the temperature rise in the body part 10 and the head part 20 of the projection device 1.

### Modification Example of Control of Fan by Control Unit 131

FIGS. 14 to 16 are flowcharts showing a modification example of the control of the fan by the control unit 131.

FIG. 14 is a flowchart showing a modification example of the control of the fan described in FIG. 12. As shown in FIG. 14, the processing from step S11 to step S13 is the same as the processing from step S11 to step S13 described in FIG. 12.

In step S12, in a case where the temperature of the DMD 115 has risen to Th1 or higher (step S12: Yes), the control unit 131 performs control of increasing the rotation speed of the second cooling fan 105 that cools the DMD 115 in the head part 20 by, for example, a predetermined amount via the communication units 132 and 133 (step S31). The control unit 131 acquires the rotation speed of the second cooling fan 105 measured by the rotation speed sensor 125 from the head part 20 via the communication units 132 and 133 after the control. The control unit 131 may calculate the rotation speed of the second cooling fan 105 based on the control value controlled by the control unit 131 in order to increase the rotation speed of the second cooling fan 105.

Next, the control unit 131 determines whether or not the rotation speed of the second cooling fan 105 is, for example, Lm2 [rpm] or higher (step S32). Lm2 is an example of the allowable upper limit value that does not cause noise as described above.

In step S32, in a case where the rotation speed of the second cooling fan 105 is not Lm2 or higher (step S32: No), the control unit 131 returns to step S11 to repeat each processing. In step S32, in a case where the rotation speed of the second cooling fan 105 is Lm2 or higher (step S32: Yes), the control unit 131 proceeds to step S18 of FIG. 13.

According to the control of the present modification example, it is possible to gradually increase the rotation speed of the second cooling fan 105 while measuring the temperature of the DMD 115, so that it is possible to further efficiently manage the temperature rise of the projection device 1.

FIG. 15 is a flowchart showing a modification example of the control of the fan described in FIG. 14. The present modification example is different from the modification example described in FIG. 14 in that a mode in which the rotation sound of the second cooling fan 105 may be heard as noise can be selected. As shown in FIG. 15, the processing from step S11 to step S13 and the processing of step S31 are the same as the processing from step S11 to step S13 and the processing of step S31 described in FIG. 14.

Next, the control unit 131 determines whether or not a noise ignore mode in the projection device 1 is effective (step S33). The noise ignore mode is a mode in which the rotation sound of the second cooling fan 105 is ignored even in a case where the rotation sound is heard as noise as described above. The noise ignore mode is, for example, effective in response to a user operation.

In step S33, in a case where the noise ignore mode is not effective (step S33: No), the control unit 131 determines whether or not the rotation speed of the second cooling fan 105 is, for example, Lm2 [rpm] or higher (step S34). Lm2 is an example of an allowable upper limit value of the noise of the second cooling fan 105. In a case where the rotation speed of the second cooling fan 105 is not Lm2 or higher (step S34: No), the control unit 131 returns to step S11 to repeat each processing. In a case where the rotation speed of the second cooling fan 105 is Lm2 or higher (step S34: Yes), the control unit 131 proceeds to step S18 of FIG. 13.

On the other hand, in step S33, in a case where the noise ignore mode is effective (step S33: Yes), the control unit 131 determines whether or not the rotation speed of the second cooling fan 105 is, for example, Lm3 [rpm] or higher (step S35). Lm3 is a rotation speed higher than Lm2, and is an example of an upper limit of the rotation speed of the second cooling fan 105. In a case where the rotation speed of the second cooling fan 105 is not Lm3 or higher (step S35: No), the control unit 131 returns to step S11 to repeat each processing. In a case where the rotation speed of the second cooling fan 105 is Lm3 or higher (step S35: Yes), the control unit 131 proceeds to step S18 of FIG. 13.

According to the control of the present modification example, it is possible to switch the upper limit value of the rotation speed of the second cooling fan 105 provided on the head part 20 side, so that it is possible to further efficiently manage the temperature rise according to the installation status of the head part 20.

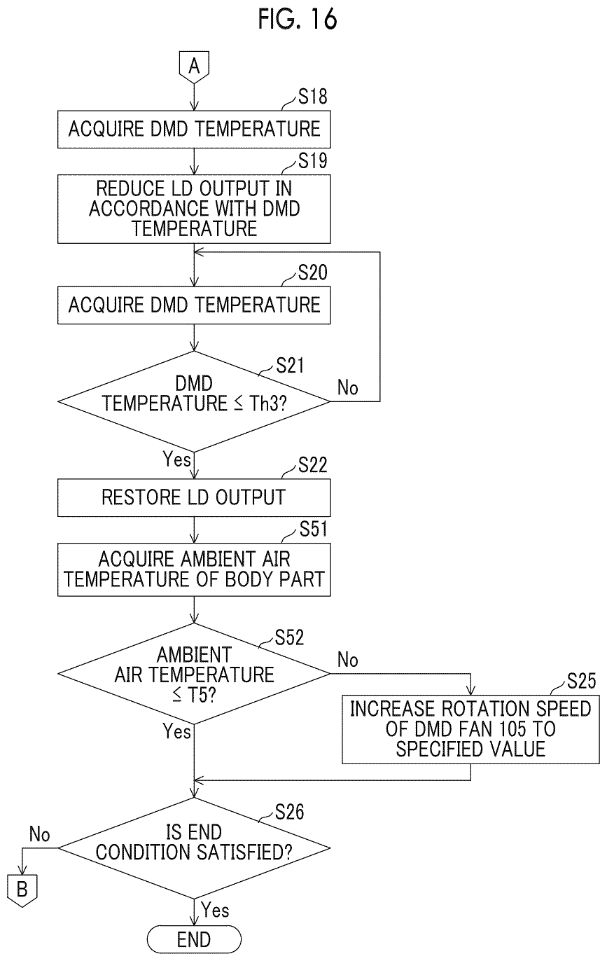

FIG. 16 is a flowchart showing a modification example of the control of the fan described in FIG. 13. As shown in FIG. 16, the processing from step S18 to step S22 is the same as the processing from step S18 to step S22 described in FIG. 13.

Next, the control unit 131 acquires the ambient air temperature of the body part 10 measured by the ambient air temperature sensor 123 of the body part 10 via the communication units 132 and 133 (step S51).

Next, the control unit 131 determines whether or not the ambient air temperature of the body part 10 acquired in step S51 is, for example, Th5 [°C] or lower (step S52). Th5 is an example of a threshold value (for example, a surrounding upper limit temperature) of the ambient air temperature on the body part 10 side.

The processing of step S25 and step S26 after the determination processing in step S52 is the same as the processing of step S25 and step S26 described in FIG. 13.

According to the control of the present modification example, the output of the LD 111 can be controlled according to the ambient air temperature of the body part 10, so that it is possible to efficiently manage the temperature rise of the projection device 1.

### Configuration Example of LCD Method Projection Device 1

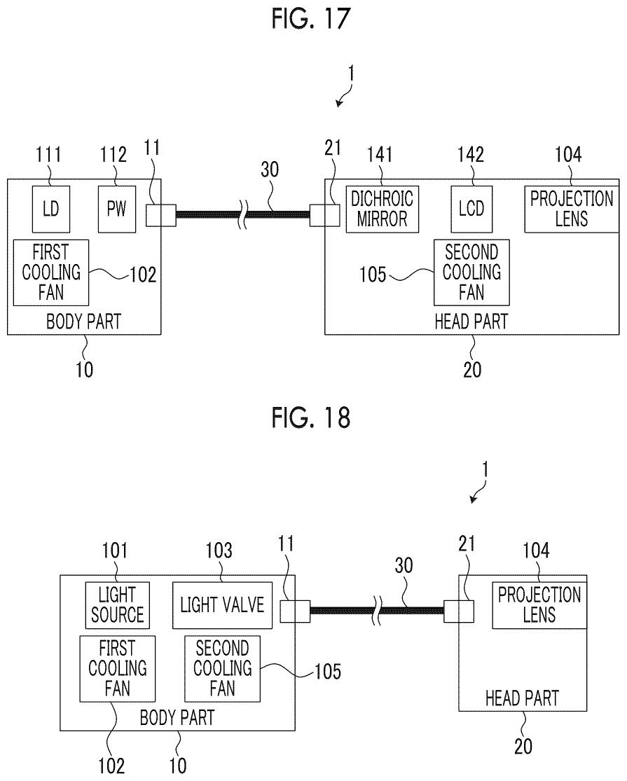

FIG. 17 is a diagram showing an example of a configuration of the projection device 1 of the LCD method. As shown in FIG. 17, the body part 10 of the projection device 1 of the LCD method comprises the LD 111, the PW 112, the first cooling fan 102, and the connector 11. In addition, the head part 20 of the projection device 1 of the LCD method comprises a dichroic mirror 141, an LCD 142, the projection lens 104, the second cooling fan 105, and the connector 21. The housing of the body part 10 and the housing of the head part 20 are communicably connected to each other by the optical fiber 30.

The LD 111 and the PW 112 correspond to the light source 101 described in FIG. 2. The dichroic mirror 141 decomposes light transmitted from the body part 10 through the optical fiber 30 into three colors of RGB, and outputs each light to the LCD 142. The LCD 142 individually transmits each light to three thin film transistor (TFT) liquid crystal panels, and then synthesizes the light with a prism. The LCD 142 corresponds to the light valve 103 described in FIG. 2.

Even in a case of the projection device 1 of the LCD method, the head part 20 can be reduced in size, and a relative positional relationship between the body part 10 and the head part 20 can be changed, so that the maintenance is easy, as in the projection device of the DLP method.

### Modification Example of Configuration of Projection Device 1

### First Modification Example

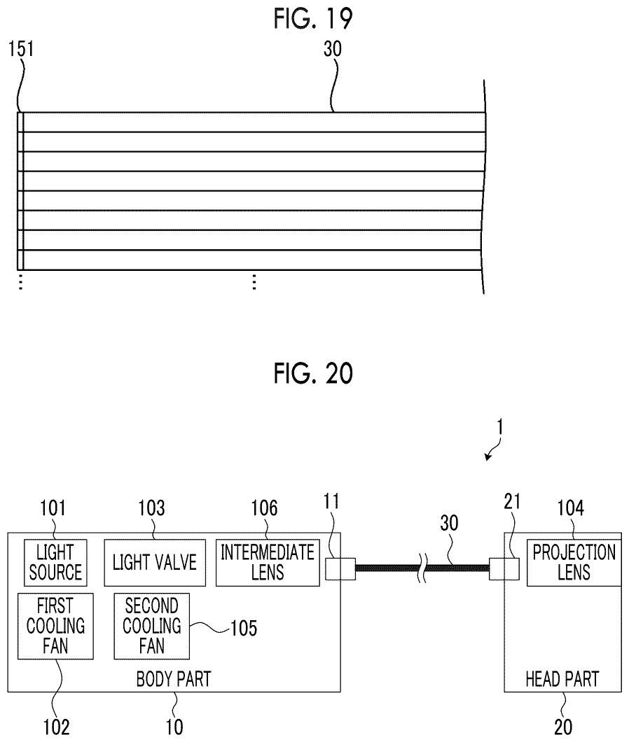

FIG. 18 is a diagram showing a first modification example of the configuration of the projection device 1. The projection device 1 of the first modification example is configured to further reduce the head part 20 by providing the light valve 103 in the body part 10 as compared with the projection device 1 shown in FIG. 2. As shown in FIG. 18, the body part 10 of the projection device 1 of the first modification example comprises the light source 101, the first cooling fan 102, the light valve 103, the second cooling fan 105, and the connector 11. In addition, the head part 20 of the projection device 1 of the first modification example comprises the projection lens 104 and the connector 21.
FIG. 19 is a diagram showing an example of a specific configuration of the first modification example shown in FIG. 18. The projection device 1 of the first modification example is an LCD method projection device in which an LCD 151 is used as the light valve 103. Although not shown, a dichroic mirror (see FIG. 17) provided in the device of the LCD method is also provided on the body part 10 side.

As shown in FIG. 19, in the projection device 1, each optical fiber in a bundle of the optical fiber 30 is optically connected to each pixel of the LCD 151. The pixel information for each pixel is transmitted to the head part 20 by one fiber. As a result, it is possible to efficiently transmit the information of each pixel to the head part 20 by one optical fiber.

### Second Modification Example

FIG. 20 is a diagram showing a second modification example of the configuration of the projection device 1. The projection device 1 of the second modification example is configured to provide an intermediate lens 106 in the body part 10 as compared with the projection device 1 of the first modification example shown in FIG. 18. The intermediate lens 106 is a lens for creating an intermediate image in a space on the body part 10 side. As shown in FIG. 20, the body part 10 of the projection device 1 of the second modification example comprises the light source 101, the first cooling fan 102, the light valve 103, the intermediate lens 106, the second cooling fan 105, and the connector 11. In addition, the head part 20 of the projection device 1 of the second modification example comprises the projection lens 104 and the connector 21.

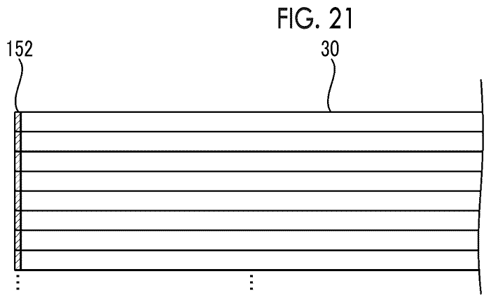

FIG. 21 is a diagram showing an example of a specific configuration of the second modification example shown in FIG. 20. The projection device 1 of the second modification example may be an LCD method projection device in which an LCD 151 is used as the light valve 103, or may be a DLP method projection device in which a DMD 115 is used as the light valve 103. As shown in FIG. 21, in the projection device 1, each optical fiber in a bundle of the optical fiber 30 is optically connected to each pixel of an intermediate image 152 generated by the intermediate lens 106. Since an intermediate image 152 having a size that matches conditions such as a diameter and a number of the optical fibers 30 can be formed, it is possible to efficiently transmit the information of each pixel to the head part 20 by one optical fiber.

The control method described in the above embodiment can be implemented by executing a control program prepared in advance via a computer. The present control program is executed by being recorded in a computer-readable storage medium and being read out from the storage medium. In addition, the present control program may be provided in a form of being stored in a non-transitory storage medium, such as a flash memory, or may be provided via a network, such as the Internet. The computer that executes the present control program may be included in the control device, may be included in an electronic apparatus such as a smartphone, a tablet terminal, or a personal computer that can communicate with the control device, or may be included in a server device that can communicate with the control device and the electronic apparatus.

Although various embodiments have been described above, it is needless to say that the present invention is not limited to such examples. It is apparent that those skilled in the art may perceive various modification examples or correction examples within the scope disclosed in the claims, and those examples are also understood as falling within the technical scope of the present invention. In addition, each constituent in the embodiment may be used in any combination without departing from the gist of the invention.

The present application is based on Japanese Patent Application (JP2023-165954) filed on Sep. 27, 2023, the content of which is incorporated in the present application by reference.

### Explanation of References

1: projection device
2: wall
3: projection image
4: floor
5: ceiling
6: mounting bracket
10, 110, 210: body part
10A, 20A: housing
10a, 20a: front surface
10b, 20b: upper surface
10c, 10d, 20c, 20d: side surface
10e, 20e: rear surface
10f, 20f: lower surface
11, 21: connector
20: head part
30: optical fiber
101: light source
102: first cooling fan
103: light valve
104: projection lens
105: second cooling fan
105a: intake fan
105b: exhaust fan
106: intermediate lens
111: LD
112: PW
113: CW
114: TIR
115: DMD
121, 124: temperature sensor
122, 125: rotation speed sensor
123, 126: ambient air temperature sensor
131: control unit
132, 133: communication unit
141: dichroic mirror
142, 151: LCD
152: intermediate image

What is claimed is:

1. A projection device comprising:
a body part including a light source and a first cooling device;
a head part including a light valve, a projection lens, and a second cooling device;
a light transmission unit configured to transmit light output from the light source to the head part; and
a processor,
wherein a housing of the body part and a housing of the head part are connected to each other via the light transmission unit,
the head part includes a first temperature sensor that includes a temperature sensor of the light valve, and
the processor is configured to
control a set value of the second cooling device and an output power of the light source based on a temperature measured by the first temperature sensor, and
control the output power of the light source based on correspondence information between a change in the output power of the light source and a change in a temperature measured by the temperature sensor of the light valve.

2. The projection device according to claim 1,
wherein the processor is configured to
perform a control of increasing the set value of the second cooling device and a control of lowering the output power of the light source in response to the temperature measured by the first temperature sensor being higher than a first threshold, and
perform the control of set value of the second cooling device in response to the temperature measured by the first temperature sensor being higher than a second threshold and equal to or lower than the first threshold.

3. The projection device according to claim 1,
wherein the head part is configured to emit, via the light valve and the projection lens, the light transmitted by the light transmission unit.

4. The projection device according to claim 1,
wherein the housing of the body part and the housing of the head part are installed at positions different from each other.

5. The projection device according to claim 1,
wherein the light transmission unit is flexible.

6. The projection device according to claim 1,
wherein the body part includes a rotary body that transmits or reflects light, and is configured to output the light emitted from the light source to the light transmission unit via the rotary body.

7. The projection device according to claim 1,
wherein the head part includes a rotary member that transmits or reflects light, and is configured to emit the light transmitted by the light transmission unit via the rotary body, the light valve, and the projection lens.

8. The projection device according to claim 1,
wherein the processor is configured to perform a control of reducing the output power of the light source in a case where the set value of the second cooling device reaches a predetermined value.

9. The projection device according to claim 8,
wherein the first cooling device and the second cooling device are cooling fans.

10. The projection device according to claim 8,
wherein the predetermined value is variable.

11. The projection device according to claim 9,
wherein the processor is configured to switch between a control of reducing the output power of the light source in a case where a rotation speed of the second cooling device reaches a first predetermined value, and control of reducing the output power of the light source in a case where the rotation speed of the second cooling device reaches a second predetermined value higher than the first predetermined value.

12. The projection device according to claim 1,
wherein the first temperature sensor includes a temperature sensor of the light valve and an ambient air temperature sensor of the head part, and
the processor is configured to control the output power of the light source based on a temperature measured by the temperature sensor of the light valve and a temperature measured by the ambient air temperature sensor of the head part.

13. The projection device according to claim 1,
wherein the processor is configured to perform a control of lowering the output power of the light source, and perform a control of increasing the output power of the light source based on a temperature measured by the first temperature sensor.

14. The projection device according to claim 13,
wherein the body part includes a second temperature sensor,
the first cooling device is a cooling fan, and
the processor is configured to perform a control of increasing the output power of the light source, and perform a control of a rotation speed of the first cooling device based on a temperature measured by the second temperature sensor.

15. The projection device according to claim 1,
wherein the body part includes a first communication unit,
the head part includes a second communication unit that communicates with the first communication unit, and
the processor is configured to perform a control by using communication between the first communication unit and the second communication unit.

16. A control method performed by a control device of a projection device including a body part including a light source and a first cooling device, a head part including a light valve, a projection lens, a second cooling device, and a first temperature sensor, and a light transmission unit that transmits light output from the light source to the head part, in which a housing of the body part and a housing of the head part are connected to each other through the light transmission unit, the head part including a first temperature sensor that includes a temperature sensor of the light valve, the control method comprising:
controlling, by a processor of the control device, a set value of the second cooling device and an output power of the light source based on a temperature measured by the first temperature sensor; and
controlling, by the processor, an output power of the light source based on correspondence information between a change in the output power of the light source and a change in a temperature measured by the temperature sensor of the light valve.

17. A non-transitory computer-readable storage medium storing a control program for a projection device including a body part including a light source and a first cooling device, a head part including a light valve, a projection lens, a second cooling device, and a first temperature sensor, and a light transmission unit that transmits light output from the light source to the head part, in which a housing of the body part and a housing of the head part are connected to each other through the light transmission unit, the head part including a first temperature sensor that includes a temperature sensor of the light valve, the control program causing a processor of the projection device to execute processing of:
controlling a set value of the second cooling device and output power of the light source based on a temperature measured by the first temperature sensor; and
controlling the output power of the light source based on correspondence information between a change in the output power of the light source and a change in a temperature measured by the temperature sensor of the light valve.
